(19) United States
(12) Patent Application Publication
(10) Pub. No.: US 2009/0133744 A1
(43) Pub. Date: May 28, 2009

(54) PHOTOVOLTAIC CELL

(75) Inventor: Hans-Josef Sterzel, Dannstadt-Schauernheim (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/577,993

(22) PCT Filed: Oct. 25, 2005
(86) PCT No.: PCT/EP05/11433

§ 371 Date: Apr. 26, 2007

(30) Foreign Application Priority Data
Oct. 26, 2004 (DE) 10 2004 052 014.3

(51) Int. Cl. H01L 31/00; B05D 5/12

(52) U.S. Cl. 136/255; 427/74; 427/76; 204/192.1; 205/92

(57) ABSTRACT

The invention relates to a photovoltaic cell comprising a photovoltaically active semiconductor material, wherein the photovoltaically active semiconductor material is a p- or n-doped semiconductor material comprising mixed compounds of the formula (I):

(Zn₁₋ₓMnₓTe)_{1-y}(SiₐTe_{b})_{y} (I)

where
x is from 0.01 to 0.99,
y is from 0.01 to 0.2,
a is from 1 to 2 and
b is from 1 to 3.

The invention relates to photovoltaic cells and the photovoltaically active semiconductor material present therein.

Photovoltaically active materials are semiconductors which convert light into electric energy. The principles of this have been known for a long time and are utilized industrially. Most of the solar cells used industrially are based on crystalline silicon (single-crystal or polycrystalline). In a boundary layer between p- and n-conducting silicon, incident photons excite electrons of the semiconductor so that they are raised from the valence band to the conduction band.

The magnitude of the energy gap between the valence band and the conduction band limits the maximum possible efficiency of the solar cell. In the case of silicon, this is about 30% on irradiation with sunlight. In contrast, an efficiency of about 15% is achieved in practice because some of the charge carriers recombine by various processes or deactivate by further mechanisms and are thus no longer effective.

DE 102 23 744 A1 discloses alternative photovoltaically active materials and photovoltaic cells in which these are present, which have the loss mechanisms which reduce efficiency to a lesser extent.

With an energy gap of about 1.1 eV, silicon has quite a good value for practical use. A decrease in the energy gap will push more charge carriers into the conduction band, but the cell voltage becomes lower. Analogously, larger energy gaps would result in higher cell voltages, but because fewer photons are available to be excited, lower usable currents are produced.

Many arrangements such as series arrangement of semiconductors having different energy gaps in tandem cells have been proposed in order to achieve higher efficiencies. However, these are very difficult to realize economically because of their complicated structure.

A new concept comprises generating an intermediate level within the energy gap (up-conversion). This concept is described, for example, in Proceedings of the 14^{th} Workshop on Quantum Solar Energy Conversion-Quantasol 2002, Mar. 17-23, 2002, Rauris, Salzburg, Austria, “Improving solar cells efficiencies by the up-conversion”, Tl. Trupke, M. A. Green, P. Würfel or “Increasing the Efficiency of Ideal Solar Cells by Photon Induced Transitions at intermediate Levels”, A. Luque and A. Marti, Phys. Rev. Letters, Vol. 78, No. 26, June 1997, 5014-5017. In the case of a band gap of 1.995 eV and an energy of the intermediate level of 0.713 eV, the maximum efficiency is calculated to be 63.17%.

Such intermediate levels have been confirmed spectroscopically, for example in the system Cd_{1-y}Mn_{y}OₓTe₁₋ₓ or Zn₁₋ₓMnₓO_{y}Te_{1-y}. This is described in “Band anticrossing in group II-OₓVl₁₋ₓ highly mismatched alloys: Cd_{1-y}Mn_{y}OₓTe₁₋ₓ quaternaries synthesized by O ion implantation”, W. Walukiewicz et al., Appl. Phys. Letters, Vol 80, No. 9, March 2002, 1571-1573, and in “Synthesis and optical properties of II-O-Vl highly mismatched alloys”, W. Walukiewicz et al., Appl. Phys. Vol 95, No. 11. June 2004, 6232-6238. According to these authors, the desired intermediate energy level in the band gap is raised by part of the tellurium anions in the anion lattice being replaced by the significantly more electronegative oxygen ion. Here, tellurium was replaced by oxygen by means of ion implantation in thin films. A significant disadvantage of this class of materials is that the solubility of oxygen in the semiconductor is extremely low. This results in, for example, the compounds Zn₁₋ₓMnₓTe_{1-y}O_{y} in which y is greater than 0.001 being thermodynamically unstable. On irradiation over a prolonged period, they decompose into the stable tellurides and oxides. Replacement of up to 10 atom % of tellurium by oxygen would be desirable, but such compounds are not stable.

Zinc telluride, which has a direct band gap of 2.32 eV at room temperature, would be an ideal semiconductor for the intermediate level technology because of this large band gap. Zinc in zinc telluride can readily be replaced continuously by manganese, with the band gap increasing to about 2.8 eV for MnTe (“Optical Properties of epitaxial ZnMnTe and ZnMgTe films for a wide range of alloy compositions”. X, Liu et al., J. Appl. Phys. Vol. 91, No. 5, March 2002, 2859-2865; “Bandgap of Zn₁₋ₓMnₓTe: non linear dependence on composition and temperature”, H. C. Mertins et al., Semicond. Sci. Technol. 8 (1993) 1634-1638).

Zn₁₋ₓMnₓTe can he doped with up to 0.2 mol % of phosphorus to make it p-conductive, with an electrical conductivity in the range from 10 to 30 Ω⁻¹cm⁻¹ (“Electrical and Magnetic Properties of Phosphorus Doped Bulk Zn₁₋ₓMnₓTe”, Le Van Khoi et al., Moldavian Journal of Physical Sciences, No. 1, 2002, 11-14). Partial replacement of zinc by aluminum gives n-conductive species (“Aluminium-doped n-type ZnTe layers grown by molecular-beam epitaxy”, J. H. Chang et al., Appl. Phys. Letters, Vol 79, No. 6, August 2001, 785-787; “Aluminium doping of ZnTe grown by MOPVE”, S. I. Gheyas et al., Appl. Surface Science 100/101 (1996) 634-638; “Electrical Transport and Photoelectronic Properties of ZnTe: Al Crystals”, T. L. Lavsen et al., J. Appl. Phys., Vol 43, No. 1, January 1972, 172-182). At degrees of doping of about 4*10¹⁸ Al/cm³, electrical conductivities of from about 50 to 60 Ω⁻¹ cm⁻¹ can be achieved.

It is an object of the present invention to provide a photovoltaic cell which has a high efficiency and a high electric power and avoids the disadvantages of the prior art. A further object of the present invention is to provide, in particular, a photovoltaic cell comprising a thermodynamically stable photovoltaically active semiconductor material which has an intermediate level in the energy gap.

This object is achieved according to the invention by a photovoltaic cell comprising a photovoltaically active semiconductor material, wherein the photovoltaically active semiconductor material is a p- or n-doped semiconductor material comprising mixed compounds of the formula (I):

(Zn₁₋ₓMnₓTe)_{1-y}(SiₐTe_{b})_{y} (I)

where
x is from 0.01 to 0.99,
y is from 0.001 to 0.2,
a is from 1 to 2 and
b is from 1 to 3.

The object of the invention is thus surprisingly achieved completely differently than would be expected from the references cited. To produce intermediate levels in the energy gap, the tellurium is not replaced by a significantly more electronegative element but instead silicon is introduced into the semiconductor material having the formula Zn₁₋ₓMnₓTe. This is surprising since the electro-negativity of silicon is 1.9 and thus differs only slightly from that of tellurium, viz. 2.1.

The variable x can be from 0.01 to 0.99, and y can be from 0.001 to 0.2, preferably from 0.005 to 0.1. The variable a can be from 1 to 2, and b can be from 1 to 3. Preference is given to a=2 and b=3, which gives the stoichiometry Si₂Te₃.

The photovoltaic cell of the invention has the advantage that the photovoltaically active semiconductor material used is thermodynamically stable even after introduction of silicon telluride. Furthermore, the photovoltaic cell of the invention has a high efficiency (up to 60%), since the silicon telluride produces intermediate levels in the energy gap of the photovoltaically active semiconductor material. Without an intermediate level, only photons having at least the energy of the energy gap could raise electrons or charge carriers from the valence band into the conduction band. Photons having a higher energy also contribute to the efficiency, with the excess energy compared to the band gap being lost as heat. In the case of an intermediate level which is present in the semiconductor material used according to the present invention and can be partly occupied, more photons can contribute to excitation.

The photovoltaic cell of the invention comprises a p-doped semiconductor material and an n-doped semiconductor material, with these two semiconductor materials being adjoined so as to form a p-n transition. Both the p-doped semiconductor material and the n-doped semiconductor material comprise substantially mixed compounds of the formula (I), with the material additionally being doped with donor ions in the p-doped semiconductor material and acceptor ions in the n-doped semiconductor material.

The p-doped semiconductor material preferably contains at least one element from the group consisting of As and P at an atomic concentration of up to 0.1 atom % and the n-doped semiconductor material preferably contains at least one clement from the group consisting of Al, In and Ga at an atomic concentration of up to 0.5 atom %. Preferred doping elements are aluminum and phosphorus.

In a preferred embodiment of the photovoltaic cell of the invention, it comprises a substrate, in particular an electrically conductive substrate, a p layer of the p-doped semiconductor material having a thickness of from 0.1 to 10 μm, preferably from 0.3 to 3 μm, and an n layer of the n-doped semiconductor material having a thickness of from 0.1 to 10 μm, preferably from 0.3 to 3 μm. The substrate is preferably a flexible metal foil or a flexible metal sheet. The combination of a flexible substrate with thin photovoltaically active layers gives the advantage that no complicated and thus expensive support has to be used for holding the solar module comprising the photovoltaic cells of the invention. In the case of nonflexible substrates such as glass or silicon, wind forces have to be dissipated by means of complicated support constructions in order to avoid breakage of the solar module. On the other hand, if deformation due to flexibility is possible, very simple and inexpensive support constructions which do not have to be rigid under deformation forces can be used. In particular, a stainless steel sheet is used as preferred flexible substrate for the purposes of the present invention.

The invention further provides a process for producing a photovoltaic cell according to the invention, which comprises coating a substrate with at least one layer of the p-doped semiconductor material and at least one layer of the n-doped semiconductor material, with the layers having a thickness of from 0.1 to 10 μm, preferably from 0.3 to 3 μm.

Coating of the substrate with the p or n layer preferably comprises at least one deposition process selected from the group consisting of sputtering, laser ablation, electrochemical deposition or electroless deposition. The previously p- or n-doped semiconductor material comprising mixed compounds of the formula (I) can be applied as a layer to the substrate by means of the respective deposition process. As an alternative thereto, a layer of the semiconductor material without p- or n-doping can firstly be produced by means of the deposition process and this layer can subsequently be p- or n-doped. The introduction according to the invention of silicon in the form of silicon telluride (if the respective layer produced by one of the abovementioned deposition processes does not yet have the appropriate structure) is preferably carried out subsequent to the deposition process (and, if appropriate, to the p- or n-doping).

One possible deposition process is coating by sputtering. The term sputtering refers to the ejection of atoms from a sputtering target serving as electrode by means of accelerated ions and deposition of the ejected material on a substrate (e.g. stainless steel). To coat a substrate according to the present invention, sputtering targets comprising zinc, manganese, tellurium and silicon, for example, are produced by melting together the constituents for sputtering or the individual constituents of the semiconductor material are sputtered onto the substrate in succession and subsequently heated to a temperature of from 400 to 900° C.

Preference is given to using zinc, manganese, tellurium and silicon having a purity of at least 99.5% for producing the sputtering target. Zinc, manganese, tellurium and silicon telluride (SiₐTe_{b}) are, for example, melted under reduced pressure at temperatures of from 1200 to 1400° C. in a dewatered fused silica tube. Doping elements for p- or n-doping are preferably introduced into the sputtering target during production of the sputtering target. The doping elements, preferably aluminum for n conduction and phosphorus for p conduction, are accordingly introduced at the beginning into the sputtering target. The compounds AlTe and Zn₃P₂ are so thermally stable that they survive the sputtering process without any significant change in stoichiometry. A layer having one doping is then firstly sputtered onto the substrate and a second layer having the opposite doping is sputtered directly thereon.

A further preferred embodiment of a deposition process which can be used according to the invention is electrochemical deposition of Zn₁₋ₓMnₓTe on the electrically conductive substrate. The electrochemical deposition of ZnTe is described in “Thin films electrodeposited on stainless steel”, A. E. Rakhsan and B. Pradup, Appl. Phys. A (2003). Pub online Dec. 19, 2003, Springer-Verlag; “Electrode-position, of ZnTe for photovoltaic alls”, B. Bozzini et al., Thin Solid Films, 361-362, (2000) 288-295; “Electrochemical deposition of ZnTe Thin films”, T. Mahalingam et al., Semicond. Sci. Technol. 17 (2002) 469-470; “Electrode-position of Zn—Te Semiconductor Film from Acidic Aqueous Solution”, R. Ichino et al., Second Internat. Conference on Processing Materials for Properties, The Minerals, Metals & Materials Society, 2000, and in U.S. Pat. No. 4,950,615, but not the electrochemical deposition of Zn/Mn/Te layers.

A process according to the invention can also comprise electroless deposition of Zn₁₋ₓMnₓTe layers by crosslinking an aqueous solution comprising Zn²⁺, Mn²⁺ and TeO₃²⁻ ions by means of hypophosphorous acid (H₃PO₂) as reducing agent at temperatures of from 30 to 90° C. in the presence of the substrate. The hypophosphorous acid reduces TeO₃²⁻ to Te²⁻. Deposition on electrically nonconductive substrates is also made possible in this way.

Depending on the deposition process, after-treatments to incorporate silicon telluride into the layers and sometimes also to introduce the dopants may be necessary.

In a preferred embodiment of the present invention, the process of the invention comprises the following process steps:
a) coating of the substrate with a first layer of Zn₁₋ₓMnₓTe.
b) introduction of silicon into the first layer to produce mixed compounds of the formula (I),
c) establishment of p- or n-doping with donor atoms or acceptor atoms,
d) coating of the first layer with a second layer of Zn₁₋ₓMnₓTe,
e) introduction of silicon into the second layer to produce mixed compounds of the formula (I),
f) establishment of n- or p-doping with acceptor atoms or donor atoms and
g) application of an electrically conductive transparent layer and a protective layer to the second layer.

In step a), the electrically conductive substrate is coated with a first layer of Zn₁₋ₓMnₓTe by for example, sputtering, electrochemical deposition or electroless deposition. The substrate is preferably a metal sheet or a metal foil.

Silicon is then introduced into this first layer in step b) to produce mixed compounds of the formula (I). The introduction of silicon is effected, for example, by applying Si₂Te₃ to the first layer by sputtering and subsequently carrying out a cocrystallization by means of a thermal after-treatment at from 600 to 1200° C., preferably from 800 to 1000° C. so as to obtain the desired composition.

In step c), the establishment of p- or n-doping is subsequently effected by doping with donor atoms or acceptor atoms. For example, the first layer is doped either with phosphorus (for example from PCl₃) to form a p conductor or with aluminum (for example from AlCl₃) to form an n conductor.

In step d), the second layer of Zn₁₋ₓMnₓTe is then deposited on the first layer. For this purpose, it is possible, for example, to employ the same deposition process as in step a).

In step e), silicon is introduced into the second layer as described for the first layer in step b).

The doping established in step f) is opposite to the doping established in step c), so that one layer is p-doped and the other layer is n-doped.

Finally, an electrically conductive transparent layer and a protective layer are applied to the second layer in step g). The electrically conductive transparent layer can be, for example, a layer of indium-tin oxide or aluminum-zinc oxide. Furthermore, it preferably has conductor tracks for establishing electrical contacts on the photovoltaic cell of the invention. The protective layer can, for example, be a layer of SiOₓ which is preferably applied by CVD or PVD. It is possible, for example, for a layer of a material which is produced in the prior art for films which keep in aromas (e.g. coffee packaging) to serve as protective layer.

### EXAMPLE 1

In accordance with the stoichiometry

(Zn_{0.5}Mn_{0.5}Te)_{0.95}(Si₂Te₃)_{0.05},

1.0350 g of Zn; 0.8669 g of Mn; 4.0407 g of tellurium and 0.7316 g of Si₂Te₃ were weighed into a fused silica tube having an internal diameter of 11 mm and a length of about 15 cm. The Si₂Te₃ was prepared separately beforehand by reacting silicon and tellurium at 1000° C. in an evacuated fused silica tube. The tube was heated at 300° C. under reduced pressure for 10 minutes to effect dewatering and then flame sealed at a pressure of less than 0.1 mbar. The tube was heated to 1300° C. at 300° C./h in a furnace, the temperature was maintained at 1300° C. for 10 hours and the furnace was then allowed to cool. During the 10 hours at 1300° C., the furnace was tilted about its longitudinal axis 30 times per hour by means of a drive in order to mix the melt in the fused silica tube.

After cooling, the fused silica tube was opened and the solidified melt was removed. The excitation levels of the material were determined by means of reflection spectroscopy. Besides the band gap of about 2.3 eV, energy levels at 0.66 eV; 0.76 eV and 0.9 eV were also found.

To produce a photovoltaic cell according to the invention, this material is sputtered onto a substrate.

### EXAMPLE 2

To effect electrochemical deposition, electrolyses were carried out in a 500 ml glass flange vessel provided with double wall, internal thermometer and bottom outlet valve. A stainless steel sheet (100×70×0.5) was used as cathode. The anode comprised MKUSF04 (graphite).

### a) Preparation of ZnTe

21.35 g of ZnSO₄.7H₂O and 55.4 mg of Na₂TeO₃ were dissolved in distilled water. This solution was brought to a pH of 2 by means of H₂SO₄ (2 mol/l) and subsequently made up to 500 ml with distilled water (Zn=0.15 mol/l; Te=0.5 mmol/l; Zn/Te=300/l). The electrolyte solution was subsequently placed in the electrolysis cell and heated to 80° C. The electrolysis was carried out over a period of 30 minutes at a current of 100.0 mA without stirring. Deposition was effected at a cathode area of ˜50 cm² (2 mA/cm²). After the electrolysis was complete, the cathode was taken out, rinsed with distilled water and dried. A copper-colored film had been deposited (18.6 mg).

Preparation of Zn₁₋ₓMnₓTe

21.55 g of ZnSO₄.7H₂O (0.15 mol/l), 47.68 g of MnSO₄.H₂O (0.6 mol/l), 33 g of (NH₄)₂SO₄ (0.5 mol/l), 1 g of tartaric acid and 55.4 mg of Na₂TeO₃ (0.5 mmol/l) were dissolved in distilled water. This solution was brought to a pH of 2 by means of H₂SO₄ (2 mol/l) and made up to 500 ml with distilled water (Zn/Mn/Te=300/1200/1). The electrolysis solution was subsequently placed in the electrolysis cell and heated to 80° C. The electrolysis was carried out over a period of 60 minutes at a current of 101.3 mA without stirring. Deposition was effected at a cathode area of ˜50 cm² (˜2 mA/cm²). After the electrolysis was complete, the cathode was taken out, rinsed with distilled water and dried. The weight gain was 26.9 mg. The deposit had a deep dark brown color.

1. A photovoltaic cell comprising a photovoltaically active semiconductor material, wherein the photovoltaically active semiconductor material is a p- or n-doped semiconductor material comprising mixed compounds of the formula (I):
(Zn₁₋ₓMnₓTe)_{1-y}(SiₐTe_{b})_{y} (I)
where
x is from 0.01 to 0.99,
y is from 0.001 to 0.2,
a is from 1 to 2 and
b is from 1 to 3.

2. The photovoltaic cell according to claim 1, wherein the p-doped semiconductor material contains at least one element from the group consisting of As and P at an atomic concentration of up to 0.1 atom % and the n-doped semiconductor material contains at least one element from the group consisting of Al, In and Ga at an atomic concentration of up to 0.5 atom %.

3. The photovoltaic cell according to claim 1 comprising a substrate, a p layer of the p-doped semiconductor material having a thickness of from 0.1 to 10 μm and an n layer of the n-doped semiconductor material having a thickness of from 0.1 to 10 μm.

4. The photovoltaic cell according to claim 3, wherein the substrate is a flexible metal foil or a flexible metal sheet.

5. A process for producing a photovoltaic cell according to claim 1, wherein a substrate is coated with at least one layer of the p-doped semiconductor material and at least one layer of the n-doped semiconductor material, with the layers having a thickness of from 0.1 to 10 μm.

6. The process according to claim 5, wherein the coating process comprises at least one deposition process from the group consisting of sputtering, laser ablation, electrochemical deposition and electroless deposition.

7. The process according to claim 6, wherein a sputtering target comprising zinc, manganese, tellurium and silicon is produced by melting together constituents for sputtering.

8. The process according to claim 7, wherein Zn, Mn, Te and Si having a purity of at least 99.5% are used for producing the sputtering target and Zn, Mn, Te and SiₐTe_{b} are melted at temperatures of from 1200 to 1400° C. under reduced pressure in a dewatered fused silica tube.

9. The process according to claim 7, wherein doping elements for p- or n-doping are introduced into the sputtering target during production of the sputtering target.

10. The process according to claim 6, wherein electroless deposition is effected by crosslinking an aqueous solution comprising Zn²⁺, Mn²⁺ and TeO₃²⁻ ions by means of hypophosphorous acid H₃PO₂ as reducing agent at a temperature of from 30 to 90° C. in the presence of the substrate.

11. The process according to claim 6 which comprises:
a) coating of the substrate with a first layer of Zn₁₋ₓMnₓTe,
b) introducing Si into the first layer to produce mixed compounds of the formula (I),
c) establishing p- or n-doping with donor atoms or acceptor atoms,
d) coating of the first layer with a second layer of Zn₁₋ₓMnₓTe,
e) introducing silicon into the second layer to produce mixed compounds of the formula (I),
f) establishing n- or p-doping with acceptor atoms or donor atoms, and
g) applying an electrically conductive transparent layer and a protective layer to the second layer.
